(19) United States
(12) Patent Application Publication
(10) Pub. No.: US 2012/0111613 A1
(43) Pub. Date: May 10, 2012

(54) COPPER FOIL WITH RESISTANCE LAYER, METHOD OF PRODUCTION OF THE SAME AND LAMINATED BOARD

(75) Inventors: Ryoichi Oguro, Tokyo (JP); Kouji Kase, Tokyo (JP); Kazuhiro Hoshino, Tokyo (JP)

(73) Assignee: FURUKAWA ELECTRIC CO., LTD., Tokyo (JP)

(21) Appl. No.: 13/384,084

(22) PCT Filed: Jul. 7, 2010
(86) PCT No.: PCT/JP10/61550

§ 371 Date: Jan. 13, 2012

(30) Foreign Application Priority Data
Jul. 14, 2009 (JP) 2009-165571

(51) Int. Cl. H05K 1/09; C23C 28/02; B32B 15/04; H05K 1/02; B32B 15/01

(52) U.S. Cl. 174/254; 174/257; 428/555; 428/551; 205/191

(57) ABSTRACT

A copper foil with a resistance layer is provided, wherein the variation value is small when it is made into a resistance element, the adhesion with the resin substrate to be laminated with is able to be sufficiently maintained, which has an excellent characteristics as a resistance element for a rigid and a flexible substrate. A copper foil with a resistance layer of the present invention comprises a copper foil on one surface of which a metal layer or alloy layer is formed from which a resistance element is to be formed, the surface of the metal layer or alloy layer being subjected to a roughening treatment with nickel particles. A method of production of a copper foil with a resistance layer of the present invention comprises: forming a resistance layer of phosphorus-containing nickel on a matte surface of an electrodeposited copper foil having crystals comprised of columnar crystal grains wherein a foundation of the matte surface is within a range of 2.5 to 6.5 μm in terms of Rz value prescribed in JIS-B-0601; and performing roughening treatment to a surface of the resistance layer with nickel particles wherein a roughness is within a range of 4.5 to 8.5 μm in terms of Rz value prescribed in JIS-B-0601. The alloy layer is for example formed from phosphorus-containing nickel.

### TECHNICAL FIELD

The present invention relates to a copper foil with a resistance layer which reduces variation of the resistance value and has excellent characteristics as a resistance element for a rigid substrate and a flexible substrate, a method of production of the same, and a laminated board using the same.

### BACKGROUND ART

Mobile electronic terminals as typified by mobile phones, even compared with electronic devices in general, have in recent years been increasingly made smaller in size and thinner in thickness and additionally been made remarkably more advanced in functions enabling them to not only handle phone calls, but also send and receive images and moving pictures of course and also provide GPS (global positioning system) functions, 1 SEG television reception, and other functions. Along with this increase in functions, the components of the mobile terminals are becoming strikingly more modularized. How to reduce the size of modules having one or more functions is the key to mounting technology and is becoming a focus point of cutting edge technology.

For example, for packages for current mobile devices, FBGA (fine pitch ball grid array) and other small-sized, thin packages have become the mainstream and are most often applied. Further, to handle the increasingly larger capacity of memories and even greater number of functions than the present, MCP (multi chip package) technology and PoP (package on package) technology have been employed.

Japanese and foreign PCB (printed circuit board) manufacturers are competing fiercely for development of WL-CSPs (wafer level chip size packages), QFNs (quad flat non-leaded packages), FBGAs, and other packages and also for development of three-dimensional chip stacking technology as technology for achieving large capacity and multifunction of the next generation. As one of these high density mounting systems, there is a device-embedded board technology.

As a method of embedding a element into a board in the device-embedded board technology, various kinds of methods have already been proposed and commercialized. However, resistors, capacitors, inductances, etc. corresponding to passive devices are restricted in processing conditions as opposed to active elements. When embedding the passive devices in a board, resistance elements are often used due to the degree of freedom of design and ease of processing.

As a thin film material to be processed to a resistance element as a passive device, there is for example metal foil with a resistance layer. As a representative type of this metal foil, there is copper foil with a resistance layer. A type of copper foil on the surface of which is electroplated a resistance element of a resistance layer having a thickness of about 0.1 μm and a type of copper foil on the surface of which a resistance layer of a thickness of about 100 to 1000 Å (0.1 to 100 nm) is formed by roll to roll sputtering are on the market.

In the metal foil of the metal foil with a resistance layer, the ratio of employment of copper foil is high due to both of handling processability and cost performance when the method of formation of the resistance layer (thin film) is either electroplating type or sputtering type.

In order to form a resistance element by such a copper foil with a resistance layer, one surface of the copper foil is bonded to the resin substrate. Roughening treatment with copper particles is performed to the surface of the copper foil which is to be a base substrate in order to raise the adhesion between the copper foil with a resistance layer and the resin substrate, and to that roughening treated surface, phosphorus-containing nickel is electrodeposited in the case of electroplating (see PTL 1 or 2), while nickel and chromium or nickel, chromium, aluminum, and silica are vapor-deposited to form a resistance layer (thin film) in the case of sputtering. Currently, among commercially available products, copper foil with a resistance layer having a resistance value of about 25 to 250Ω/□ is being sold.

In recent years, as the optimum material for reducing thickness in the design of a substrate having embedded active elements and passive devices, demand for the use of a metal foil with a resistance layer is rising. Further, in order to increase the freedom of design when embedding passive devices in the substrate, a material which can be applied to not only a rigid substrate, but also a flexible substrate is being demanded.

Further, in a circuit design using a metal foil with a resistance layer, designing the required resistance value by changing the aspect ratio of the width and length of the circuit is a general technique. However, demand for improving the precision of the passive element resistance value after fine etching along with recent microcircuit design has been rising. Further, metal foil with a resistance layer having an elongation characteristic enabling suitable bending so as to match with the flexible substrate is being demanded.

In the materials currently put by the applicant on the market, there is a copper foil with a resistance layer dealing with fine patterns. This structure is disclosed in PTLs 1 to 3, and all of these materials have structures of copper foil having microcrystalline structures which are subjected to a roughening treatment with fine copper particles according to necessity, then are electroplated in a phosphorus-containing nickel bath. However, it is difficult to obtain a uniform distribution of roughening particles on the surface of the copper foil by the fine roughening treatment. If unevenness occurs in the distribution of roughening particles, variation occurs in the thickness of the electroplated thin film layer of the phosphorus-containing nickel (which is to be a resistance element) formed thereon. This causes the problem of a larger variation in individual resistance values obtained in the in-plane resistance value measurement method prescribed in JIS-K-7194. Consequently, even if a resistance element pattern is formed along the circuit design, there is a possibility that the theoretical resistance value will not be obtained. For this reason, conventionally, in the roughening treatment step and in the electroplating step for controlling the resistance values to constant values, tremendous skill was required.

### CITATION LIST

### Patent Literature

PTL 1: Japanese Patent Publication (A) No. 2003-200523
PTL 2: Japanese Patent Publication (A) No. 2003-200524
PTL 3: Japanese Patent Publication (A) No. 2004-315843

### SUMMARY OF INVENTION

### Technical Problem

The present invention provides a copper foil with a resistance layer having a small variation of resistance values even in a case where it is processed to a resistance element, being capable of sufficiently maintaining the JPCA standard (JPCA-EB01) regarding the adhesion with the resin substrate to be laminated, and having excellent characteristics as a resistance element for a rigid substrate and a flexible substrate, a method of production of the same, and a laminated board using the same.

### Solution to Problem

The copper foil with a resistance layer of the present invention comprises a copper foil on one surface of which a metal layer or alloy layer is formed from which a resistance element is to be formed, the surface of the metal layer or alloy layer being subjected to a roughening treatment with nickel particles.

The copper foil with a resistance layer of the present invention is a copper foil with a resistance layer comprising a copper foil on one surface of which a metal layer or alloy layer is formed form which a resistance element is to be formed, the surface of the metal layer or alloy layer being subjected to a roughening treatment with nickel particles, the surface subjected to the roughening treatment being plated by capsule plating.

The copper foil with a resistance layer of the present invention comprises a copper foil on one surface of which a metal layer or alloy layer is formed from which a resistance element is to be formed, the surface of the metal layer or alloy layer being subjected to a roughening treatment with nickel particles, on the surface subjected to the roughening treatment a chromate rust prevention layer being formed.

Further, the copper foil with a resistance layer of the present invention comprises a copper foil on one surface of which a metal layer or alloy layer is formed from which a resistance element is to be formed, the surface of the metal layer or alloy layer being subjected to a roughening treatment with nickel particles, on the surface subjected to the roughening treatment a chromate rust prevention layer being formed, and on the surface of the rust prevention layer a thin film layer of a silane coupling agent being formed.

A method of production of a copper foil with a resistance layer of the present invention comprises forming a resistance layer of phosphorus-containing nickel on a matte surface of an electrodeposited copper foil having crystals comprised of columnar crystal grains wherein a foundation of the matte surface is within a range of 2.5 to 6.5 μm in terms of Rz value prescribed in JIS-B-0601, and performing roughening treatment to a surface of the resistance layer with nickel particles. The roughening treatment with nickel particles is performed so that a surface roughness is within a range of 4.5 to 8.5 μm in terms of Rz value prescribed in JIS-B-0601.

The reason for the use of the electrodeposited copper foil having crystals comprised of columnar crystal grains in the present invention is that the matte surface of the electrodeposited copper foil having crystals comprised of columnar crystal grains has a suitable roughness. When the matte surface of the electrodeposited copper foil is comprised of microcrystalline grains, it is hard to obtain electrodeposited copper foil having a surface roughness Rz value targeted by the present invention which satisfies the range of 2.5 to 6.5 μm, and that is not preferable for the base foil of the present invention. The electrodeposited copper foil having crystals comprised of columnar crystal grains can be fabricated by using a generally used electrolytic solution obtained by adding thiourea or chlorine to the composition of the electrolytic solution. A base foil can be obtained which has a substantial undulating shape and is in the range of 2.5 to 6.5 μm in terms of Rz value prescribed in JIS-B-0601.

A laminated board of the present invention is a laminated board comprising the copper foil with the resistance layer mounted on a rigid substrate or a flexible substrate having an embedded device, the copper foil with the resistance layer being patterning etched.

### Advantageous Effects of Invention

According to the copper foil with a resistance layer of the present invention, it is possible to provide a copper foil with a resistance layer having a small variation of resistance values as a resistance element, being capable of sufficiently maintaining the JPCA standard (JPCA-EB01) regarding the adhesion with the resin substrate to be laminated, and having suitable elasticity and plasticity and folding resistance so as to be capable of match with bending in a range of R=0.8 to 1.25 (mm).

Further, according to the method of production of the copper foil with a resistance layer of the present invention, it is possible to produce a copper foil with resistance layer having a small variation of resistance values even in a case where it is processed to a resistance element, being capable of sufficiently maintaining the JPCA standard (JPCA-EB01) regarding the adhesion with the resin substrate to be laminated, and having suitable elasticity and plasticity and folding resistance so as to be capable of match with bending in a range of R=0.8 to 1.25 (mm).

According to the laminated board of the present invention, it is possible to provide a laminated board formed by laminating a resin substrate and a copper foil with a resistance layer, being capable of sufficiently maintaining the JPCA standard (JPCA-EB01) regarding the adhesion with the resin substrate, and having a small variation of resistance value.

### BRIEF DESCRIPTION OF DRAWINGS

FIG. 1A to FIG. 1D are cross-sectional explanatory drawings showing cross-sections of a product in order of steps of formation of copper foil with a resistance layer.

FIG. 2 is a drawing of process showing one example of the production process after the formation of the resistance layer of the copper foil with the resistance layer.

### DESCRIPTION OF EMBODIMENTS

Below, copper foil with a resistance layer of the present invention will be explained in detail.

The copper foil with a resistance layer of the present invention comprises a copper foil on one surface of which a metal layer or alloy layer is formed from which a resistance element is to be formed, the surface of the metal layer or alloy layer being subjected to a roughening treatment with nickel particles. As the metal or alloy which is to be the resistance element, nickel and phosphorus-containing nickel are preferred.

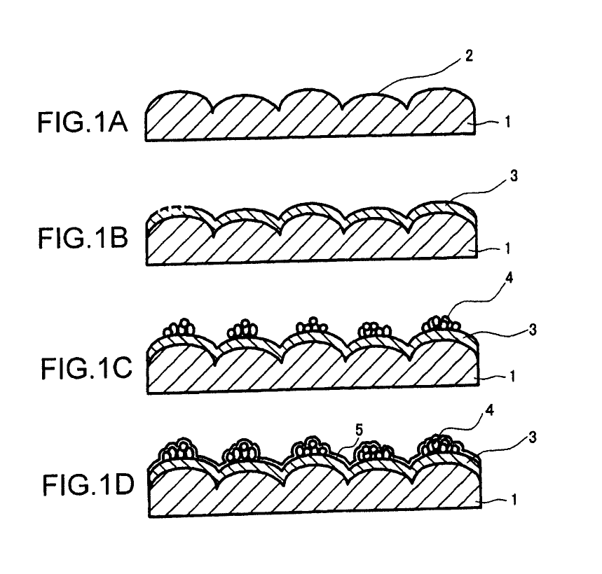

FIG. 1A to FIG. 1D show an embodiment of the present invention enlarged. FIG. 1A shows a cross-section of an electrodeposited copper foil 1. The surface of a matte surface 2 of the copper foil is comprised of columnar crystal grains within a range of 2.5 to 6.5 μm in terms of Rz value prescribed in JIS-B-0601. Here, the reason for limitation of the surface roughness Rz value of the electrodeposited copper foil 1 to the range of 2.5 to 6.5 μm is that if the surface roughness is less than 2.5 μm, sufficient adhesion with the resin substrate cannot be obtained even when the roughening treatment is performed in the next step or later, while if it exceeds 6.5 μm, the adhesive strength with the resin substrate is excellent, but the surface area increases and, at the time of formation of a high resistance element film of 250Ω/□ (film having a very thin thickness), the plating thickness becomes conspicuously uneven, so it is difficult to form a uniform resistance film. Note that, the surface roughness of the electrodeposited copper foil is preferably 3.0 to 5.5 μm in terms of the Rz value.

The copper foil 1 is preferably an electrodeposited copper foil. Particularly preferably, an electrodeposited copper foil with an elongation at ordinary temperature of 12% after heating at 180° C. for 60 minutes under atmospheric heating conditions is employed. Sometimes a copper foil, particularly a rolled copper foil, has a crystal structure which plastically deforms and becomes larger in a hot forming temperature region in a heating process for lamination with the resin substrate. If the crystal ends up becoming large, when preparing a fine pattern, not only the pattern straightness after etching becomes bad, but also the etching factor is inferior. For this reason, by limiting the elongation to 12% or more even under conditions of approximately 180° C., which is the generally used hot pressing temperature, substantial crystal grain shapes can be maintained even in heat treatment in the lamination step and the linear expansion coefficient of the resin substrate can be followed. Therefore, it becomes possible to preferably handle rigid and flexible substrates. Note that the elongation under conditions of approximately 180° C. is more preferably 13.5% or more. Here, the elongation is measured based on IPC-TM-650.

Note that, usually, if the elongation at ordinary temperature after electrodepositing foil production is 8% or more, the elongation at ordinary temperature after heating at 180° C. for 60 minutes under atmospheric heating conditions becomes 12% or more.

FIG. 1B shows a state where a resistance layer 3 is formed on the matte surface of the copper foil 1, in which the surface of the resistance layer 3 is finished so that the Rz value is in the range of 2.5 to 6.5 μm.

FIG. 1C shows a state where the surface of the resistance layer 3 is subjected to roughening treatment with nickel particles. Nickel fine particles 4 are particularly concentratedly deposited at peak parts of the resistance layer 3. The roughness after the nickel roughening treatment is preferably controlled to a range of 4.5 to 8.5 μm in terms of Rz value prescribed in JIS-B-0601. The limitation of the surface roughness Rz after the roughening treatment to the range of 4.5 to 8.5 μm is made for preventing migration defects after the fine pattern formation. That is, this is because migration, drop out of roughening particles, and other inconveniences are liable to occur if Rz exceeds the upper limit 8.5 μm, while the adhesive strength with the resin substrate is liable to be no longer satisfactory if Rz is less than the lower limit 4.5 μm. Note that, more preferably the roughness after the nickel roughening treatment is 4.8 to 7.5 μm in terms of Rz value.

FIG. 1D shows a state where smooth plating, so-called “capsule plating” 5, is performed so as to cover the surface of the nickel fine particles 4 to an extent where the nickel fine particles 4 will not drop out. The nickel fine particles 4 become substantial by performing the capsule plating 5.

Note that, in the present invention, when performing capsule plating after the nickel roughening treatment, preferably a chromate rust prevention layer (not shown) is formed on the surface after that. The amount of deposition of chromium in the rust prevention layer is preferably controlled to 0.005 to 0.045 mg/dm² as chromium metal. The reason for the control of the amount of deposition of chromium to 0.005 to 0.045 mg/dm² is that the occurrence of the inconvenience in quality such as oxidation tarnishing can be prevented if only satisfying the amount of deposition. Note that, more preferably, it is 0.005 to 0.030 mg/dm².

If a chemical thin film layer (not shown) comprised of a silane coupling agent is formed on the surface of the rust prevention layer, the adhesion with the resin substrate can be further improved, so this is desirable. The amount of deposition of the silane coupling agent is desirably controlled to 0.001 to 0.015 mg/dm² as silicon. Note that, more preferably, it is 0.003 to 0.008 mg/dm².

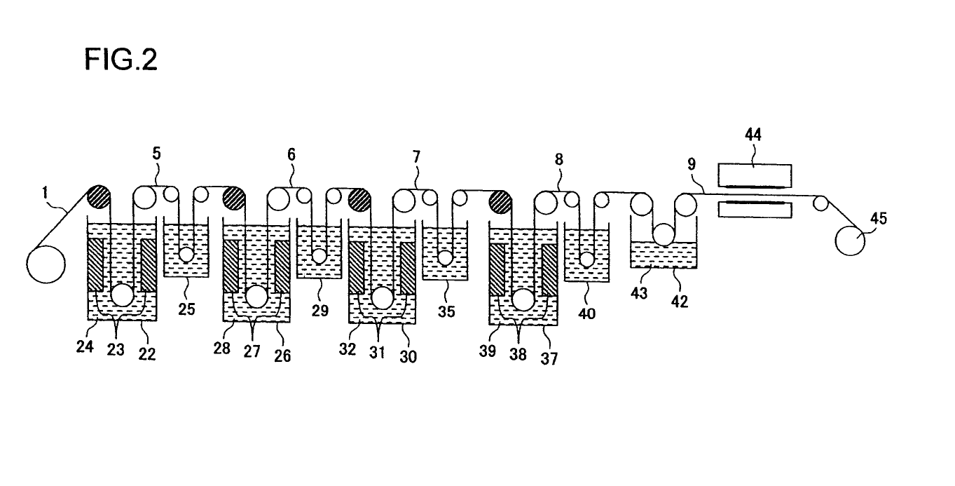

Next, an embodiment of the method of production of copper foil with a resistance layer of the present invention with reference to FIG. 2 will be explained.

In FIG. 2, a base substrate copper foil (electrodeposited copper foil, hereinafter simply referred to as “copper foil”) 1 taken up around a reel is guided to a first treatment tank 22 for forming a resistance layer 3. An iridium oxide anode 23 is placed in the first treatment tank 22, an Ni—P electrolytic solution 24 is filled, and the resistance layer 3 is formed. A copper foil 5 on which the resistance layer 3 is formed in the first treatment tank 22 is washed in a rinse tank 25, then guided to a second treatment tank 26.

An iridium oxide anode 27 is placed in the second treatment tank 26, an Ni electrolytic solution 28 is filled, and nickel roughening treatment is performed. A copper foil 6 subjected to the nickel roughening treatment is washed in a rinse tank 29, then guided to a third treatment tank 30. An iridium oxide anode 31 is placed in the third treatment tank 30, a Ni electrolytic solution 32 is filled, and capsule plating is performed. A copper foil 7 subjected to the capsule plating in the third treatment tank 30 is washed in a rinse tank 35, then guided to a fourth treatment tank 37. An SUS anode 38 is placed in the fourth treatment tank 37, a chromate electrolytic solution 39 is filled, and a chromate rust prevention layer is formed. A copper foil 8 to which the chromate rust prevention layer is formed in the fourth treatment tank 37 is washed in a rinse tank 40, then guided to a fifth treatment tank 42. A silane solution 43 is filled in the fifth treatment tank 42, then a silane coupling agent is coated on the surface of the copper foil 8. A copper foil 9 coated with the silane coupling agent in the fifth treatment tank 42 passes through a drying process 44 and is taken up around a winding reel 45.

It is also possible to use rolled copper foil as the base substrate copper foil 1. However, in order to reduce variation of the resistance layer, preferably use is made of copper foil which is produced according to electrodepositing foil production conditions for general use, has a thickness of 12 μm or more, has a shape roughness after the electrodepositing foil production of the matte surface 2 (electrolytic solution surface side) within the range of 2.5 to 6.5 μm in terms of Rz value prescribed in JIS-B-0601, and has elongation after 180° C. for 60 minutes under atmospheric heating conditions of 12% or more.

The resistance layer 3 formed on the matte surface 2 of the copper foil 1 is formed according to a cathode electroplating method using a phosphorus-containing nickel bath in the first treatment tank 22.

In the nickel bath containing phosphorus for forming the resistance layer 3, by setting the nickel sulfamate to 60 to 70 g/l as nickel, phosphorous acid to 35 to 45 g/l as PO₃, hypophosphorous acid to 45 to 55 g/l as PO₄, boric acid (HBO₃) to 25 to 35 g/l, pH to 1.6, and bath temperature to 53 to 58° C. and by controlling the electroplating current density to 4.8 to 5.5 A/dm², a copper foil with a resistance layer having very small variation of in-plane resistance and having 25 to 250Ω/□ in terms of an in-plane resistance value based on the measurement method prescribed in JIS-K-7194 can be produced.

However, in the above process, roughening treatment is not performed to the surface of the copper foil, therefore the adhesion with the resin substrate is inferior. For this reason, in the present invention, suitable roughening treatment with nickel is performed in the next step and the adhesion with the resin substrate is improved so as to meet the requirements for applications for boards having embedded resistance layers.

As the method of performing suitable roughening treatment of nickel, as shown in FIG. 2, burnt plating of nickel is performed at first by using a dissolved nickel bath (second treatment tank 26). The composition of the dissolved nickel bath for performing the burnt plating is not particularly limited so far as it is a soluble nickel compound, and the bath composition is preferable wherein 15 to 20 g/l as nickel using nickel sulfate, 18 to 25 g/l of ammonium sulfate, and 0.5 to 2 g/l as copper metal from the copper compound as an additive for forming fine nickel roughening particles, and preferably, the bath temperature is in a range of 25 to 35° C., the pH is finely adjusted by sulfuric acid and nickel carbonate to 3.5 to 3.8, and then treatment is performed at a cathode electrolytic current density of a range of 40±2 A/dm².

Next, to an extent where roughening particles formed by the nickel burnt plating do not drop out, smooth plating, so-called capsule plating, is performed using a nickel sulfate bath (third treatment tank 30) to make the nickel roughening particles substantial.

The dissolved nickel bath for performing the nickel burnt plating may be diverted basically to the bath composition of the capsule plating for preventing drop out of fine nickel particles after burnt plating, and it is preferable that nickel sulfate is used, the nickel is adjusted to 35 to 45 g/l, and the boric acid is adjusted to 23 to 28 g/l, and preferably, the bath temperature is in a range of 25 to 45° C., the pH is finely adjusted by sulfuric acid and nickel carbonate to 2.4 to 2.8, and then treatment is performed at a cathode electrolytic current density of a range of 10±2 A/dm².

As the treatment conditions of the capsule plating, it is preferable that the bath temperature is in a range of 30 to 40° C., the pH is finely adjusted by sulfuric acid and nickel carbonate to 2.4 to 2.6, and then smooth plating treatment is performed at a cathode electrolytic current density of 10 A/dm².

The object of performing the capsule plating is to prevent the drop out of nickel particles of the roughening treatment performed with the nickel particles. If too thin, the drop out of nickel particles cannot be prevented, while if too thick, variation will be caused in the resistance value of the resistance layer. Accordingly, the thickness of the capsule plating is preferably set to about ¼ to 1/10 of the thickness of the resistance layer 3.

The rust prevention treatment is performed after the capsule plating process, it may be chromate rust prevention and also may be rust prevention treatment by an organic rust prevention agent such as benzotriazole or its derivative compound. However, chromium rust prevention by a chromic acid solution is preferable since it is excellent in cost performance whether continuous treatment or single substrate treatment.

In the rust prevention treatment, the chromate rust prevention agent is provided by dip treatment, or cathode electrodepositing treatment (fourth treatment tank 37) is performed according to necessity to raise the rust prevention property.

In the coating film in the rust prevention treatment, in the case of chromate treatment, the amount of the chromium metal is in the range of 0.005 to 0.045 mg/dm², while in the case of organic rust prevention treatment, benzotriazole (1,2,3-benzotriazole (general name: BTA)) is preferable. However, a commercially available derivative is possible too. As the treatment amount thereof, dip treatment is performed to an extent where the surface does not suffer from copper oxide tarnishing until 24 hours have passed under conditions of a salt water spray test (concentration of salt water: 5% of NaCl, and temperature: 35° C.) prescribed in JIS-Z-2371.

Further, it is preferable that a silane coupling agent is suitably coated on the rust prevention layer (fifth treatment tank 42) according to necessity to raise the adhesion with the rigid resin substrate or flexible substrate. Each silane coupling agent has affinity with the resin substrate concerned, for example, if an epoxy substrate, an epoxy silane coupling agent has affinity therewith and if a polyimide resin substrate, an amino silane coupling agent has affinity therewith, therefore the type is not limited in the present invention. However, for at least chemically improving the adhesion with the resin substrate, the deposition amount of the silane coupling agent on the matte surface side is preferably in a range of 0.001 to 0.015 mg/dm² as silicon.

The above explanation was given for the continuous surface treatment of the copper foil based on FIG. 2, but surface treatment of a single substrate of copper foil can be also performed under similar treatment conditions.

The reasons for the use of phosphorus-containing nickel for formation of the resistance layer 3 explained above are the ease of the conditions for forming the bath and the ability of the resistance value of the resistance layer to be managed by the amount of deposition of nickel, the phosphorus content, and the ratio of the same. In particular, when nickel sulfamate is used, the residual plating stress after forming the thin film is small, so warping is suppressed, therefore, there is merit in terms of both improvement of productivity and stability of quality.

Here, the reasons for the use of the matte surface side of the generally used electrodeposited copper foil in order to form the resistance layer are that the plating can be uniformly performed without making it porous so long as the roughened surface shape is in the range of 2.5 to 6.5 μm in terms of Rz value even if the thickness of the thin film is the thickness of the electroplated layer giving a resistance value of about 250Ω/□, and that it is possible to form substantial fine nickel roughening particles without inconveniencing the nickel roughening treatment for imparting adhesion in the next step.

The reason for the use of the electrodeposited copper foil having good elongation is that with both a rigid substrate and a flexible substrate, the foil is suitably elastically plasticized even at the time of conveyance through the hot press step in the primary lamination process to thereby give rise to the effect of suppressing warping and curling defects at the edge surface.

The electrodeposited copper foil having good elongation is easily obtained by adding known additives into the electrolytic solution at the time of production of the electrodepositing foil.

### Example 1

Use was made of copper foil (MP foil made by Furukawa Electric Co., Ltd.) which was produced under electrodepositing foil production conditions, had a thickness of 18 μm, had a shape roughness on the matte surface side (electrolytic solution surface side) of 4.8 μm in terms of the Rz value prescribed in JIS-B-0601, and had an elongation after heating at 180° C. for 60 minutes under atmospheric heating conditions of 14.2% so as to form a resistance layer thin film for forming a resistance element body on the matte surface side, perform nickel roughening treatment, and perform capsule plating treatment under the following conditions.

[Resistance Layer-Forming Bath Composition and Treatment Conditions]

As nickel, using nickel sulfamate . . . 65 g/l

As PO₃ of phosphorous acid . . . 40 g/l

As PO₄ of hypophosphorous acid . . . 50 g/l

Boric acid (HBO₃) . . . 30 g/l

pH: 1.6

Bath temperature: 55° C.

Electroplating current density . . . 5.0 A/dm²

[Nickel Roughening Treatment Conditions]

As nickel, using nickel sulfate . . . 18 g/1

Ammonium sulfate . . . 20 g/l

As additive, as copper metal from copper sulfate compound . . . 1.2 g/l

pH: 3.6

Bath temperature: 30° C.

Electroplating current density . . . 40 A/dm²

[Capsule Plating Treatment Conditions]

As nickel, using nickel sulfate . . . 40 g/l

Boric acid (HBO₃) . . . 25 g/l

pH: 2.5

Bath temperature: 35° C.

Electroplating current density . . . 10 A/dm²

The rust prevention treatment of the examples was performed by dipping in a bath containing 3 g/l of CrO₃ and after drying, an epoxy silane coupling agent (Sila-Ace S-510 made by Chisso Corporation) in bath prepared to 0.5 wt % was coated on only the matte surface side of the copper foil to form a thin film.

The obtained copper foil with a resistance layer was cut into 250 mm square pieces. Their resistance layer sides (matte surface sides) were superimposed on commercially available resin substrates (LX67F prepregs made by Hitachi Chemical Ltd. were used) and hot pressed to prepare copper-clad laminated boards with single-side resistance layer. Just the copper foils were selectively etched by an alkali etchant of the tradename “A-Process-W” made by Meltex Inc., then 20 test pieces were measured by the 4-terminal 4-pin probe method (constant current system) by a resistance meter Lorester GP/MCP-T610 made by Dia Instruments Co., Ltd. in accordance with the measurement method of the in-plane resistance value prescribed in JIS-K-7194. The variation indicator sigma (a) of a total of 180 measurement values was found by statistical techniques and was described in Table 1.

Further, the adhesion (adhesive strength) with the resin substrate material was measured according to the measurement method prescribed in JIS-C-6481. In evaluation of whether the foil had a suitable elasticity and plasticity or not, the elongation (elongation at ordinary temperature) was measured in the state of the foil before lamination according to the measurement method prescribed in IPC-TM-650, while the extent of plasticity (0.8R/MIT folding resistance) was measured according to the measurement method (R=0.8 mm) of flex resistance prescribed in JIS-P-8115. The results are described in Table 1.

Further, the nickel residue after the etching shown in Table 1 is judged according to the results of observation by an optical microscope.

The judgment criteria is as follows. The inside of a 25.4 mm-sized square (1-inch square) etching surface was observed visually at a magnification of 100. Samples where no residue at all was seen were evaluated as “very good”, samples where number of five or less residues of less than 10 μm size were seen were evaluated as “good”, samples where number of less than ten residues of 10 μm to less than 30 μm size were seen were evaluated as “fair”, and samples where number of ten or more residues of 10 μm to less than 30 μm size to be judged as having practical problems were seen were evaluated as “poor”.

### Example 2

Except for the use of a copper foil (MP foil produced by Furukawa Electric Co., Ltd.) which was produced under electrodepositing foil production conditions, had a thickness of 18 μm, had a shape roughness on the matte surface side of 4.5 μm in terms of Rz value prescribed in JIS-B-0601, and had an elongation after heating at 180° C. for 60 minutes under atmospheric heating conditions of 14.2%, treatments were carried out under the conditions described in Example 1 for subjecting to the evaluation and measurement.

The results of measurement and evaluation are described in Table 1.

### Example 3

Except for the use of a copper foil (MP foil produced by Furukawa Electric Co., Ltd.) which was produced under electrodepositing foil production conditions, had a thickness of 18 μm, had a shape roughness on the matte surface side of 4.5 μm in terms of Rz value prescribed in JIS-B-0601, and had an elongation after heating at 180° C. for 60 minutes under atmospheric heating conditions of 12.0%, treatments were carried out under the conditions described in Example 1 for subjecting to the evaluation and measurement.

The results of measurement and evaluation are described in Table 1.

### Example 4

Except for the use of a copper foil (MP foil produced by Furukawa Electric Co., Ltd.) which was produced under electrodepositing foil production conditions, had a thickness of 18 μm, had a shape roughness on the matte surface side of 8.5 μm in terms of Rz value prescribed in JIS-B-0601, and had an elongation after heating at 180° C. for 60 minutes under atmospheric heating conditions of 12.0%, treatments were carried out under the conditions described in Example 1 for subjecting to the evaluation and measurement.

The results of measurement and evaluation are described in Table 1.

### Example 5

Except for the use of a copper foil (MP foil produced by Furukawa Electric Co., Ltd.) which was produced under electrodepositing foil production conditions, had a thickness of 18 μm, had a shape roughness on the matte surface side of 3.5 μm in terms of Rz value prescribed in JIS-B-0601, and had an elongation after heating at 180° C. for 60 minutes under atmospheric heating conditions of 12.0%, treatments were carried out under the conditions described in Example 1 for subjecting to the evaluation and measurement.

The results of measurement and evaluation are described in Table 1.

### Comparative Example 1

Except for the use of a copper foil (MP foil produced by Furukawa Electric Co., Ltd.) which was produced under electrodepositing foil production conditions, had a thickness of 18 μm, had a shape roughness on the matte surface side of 9.2 μm in terms of Rz value prescribed in JIS-B-0601, and had an elongation after heating at 180° C. for 60 minutes under atmospheric heating conditions of 12.0%, treatments were carried out under the conditions described in Example 1 for subjecting to the evaluation and measurement.

The results of measurement and evaluation are described in Table 1.

### Comparative Example 2

Except for performing copper burnt plating at the matte surface side of the base substrate copper foil used in Example 1 under the following treatment conditions, then performing capsule plating of copper, then electroplating the resistance layer thin film for forming the resistance element body using a phosphorus-containing nickel sulfamate bath, treatments were carried out under the conditions described in Example 1 for subjecting to the evaluation and measurement.

The results of measurement and evaluation are described in Table 1.

[Copper Roughening Treatment Conditions]

As copper metal, using copper sulfate . . . 23.5 g/l

Sulfuric acid . . . 100 g/l

As additive, as molybdenum from molybdenum compound . . . 0.25 g/l

Bath temperature: 25° C.

Electroplating current density 38 A/dm²

[Copper Capsule Smooth Plating Treatment Conditions]

As copper metal, using copper sulfate . . . 45 g/1

Sulfuric acid . . . 120 g/l

Bath temperature: 55° C.

Electroplating current density . . . 18 A/dm²

### Comparative Example 3

Except for changing the base substrate copper foil used in Example 1 to a 17.5 μm thick rolled copper foil and electroplating the resistance layer thin film for forming the resistance element body on only one side by using a phosphorus-containing nickel sulfamate bath, treatments were carried out under the conditions described in Example 1 for subjecting to the evaluation and measurement.

The results of measurement and evaluation are described in Table 1.

TABLE 1

| | In-plane | | | 0.8R/MIT | Elongation |
|---|---|---|---|---|---|
| | variation | Adhesive | Nickel | folding | at ordinary |
| | σ value | strength | residue | resistance | temperature |
| | (n = 180) | [kg/cm] | evaluation | [times] | [%] |
| Example 1 | 0.55 | 1.05 | Very good | 252 | 9.8 |
| Example 2 | 0.53 | 1.03 | Very good | 252 | 9.8 |
| Example 3 | 0.58 | 1.01 | Very good | 248 | 9.2 |
| Example 4 | 0.62 | 1.35 | Good | 248 | 9.2 |
| Example 5 | 0.48 | 0.74 | Very good | 248 | 9.2 |
| Comparative | 0.87 | 1.38 | Fair | 248 | 9.2 |
| Example 1 | | | | | |
| Comparative | 0.93 | 1.12 | Good | 278 | 9.8 |
| Example 2 | | | | | |
| Comparative | 0.32 | 0.08 | Very good | 198 | 3.4 |
| Example 3 | | | | | |

As apparent from the table, the in-plane variations of the copper foils with resistance layers in Examples 1 to 5 are small values of less than 0.80. These are sufficiently satisfactory for resistance elements to be embedded in resin substrates.

Usually, when the thickness is 18 μm or so, if the adhesive strength with the resin substrate is 0.70 kg/cm or more there is no practical problem, and further, if it is 1.35 kg/cm or less, there is also no concern over the nickel residue causing any problems in quality. The adhesions of the copper foils with resistance layers of all of Examples 1 to 5 satisfy this numerical range, therefore there are no problems in either the adhesive strength and nickel residue. Further, the folding resistances of the copper foils with resistance layers of Examples 1 to 5 sufficiently satisfied the required characteristics.

Further, the elongations at ordinary temperature after the electrodepositing foil production were 8% or more, that is, satisfactory, in all of Examples 1 to 5.

On the other hand, in Comparative Example 1, use was made of a base substrate copper foil having a shape roughness after electroplating of 9.2 μm in terms of Rz value prescribed in JIS-B-0601, therefore the adhesion of the finished copper foil with a resistance layer became as large as 1.38 kg/cm. However, the in-plane variation of the resistance layer was large, and the nickel residues were relatively numerous as well, so the result was poor in practicality.

Further, the copper foil with a resistance layer in Comparative Example 2 had a large in-plane variation, while the foil in Comparative Example 3 had an in-plane variation smaller than that in Example 1, but was not satisfactory in either the adhesive strength or the folding resistance, so the result was poor in practicality.

As explained above, the copper foil with a resistance layer of the present invention has a sufficiently a small variation of resistance values as a resistance element, is capable of sufficiently maintaining the adhesion with the resin substrate to be laminated, and has a suitable elasticity and plasticity and folding resistance so as to be capable of match with bending.

Further, the method of production of the copper foil with a resistance layer of the present invention can produce a copper foil with a resistance layer having a sufficiently a small variation of resistance values as a resistance element, being capable of sufficiently maintaining the adhesion with the resin substrate to be laminated, and having a suitable elasticity and plasticity and folding resistance so as to be capable of match with bending.

According to the laminated board of the present invention, the adhesion with the resin substrate is sufficiently maintained, so it is a laminated board with little variation of resistance value.

### INDUSTRIAL APPLICABILITY

The copper foil with resistance layers according to the present invention and the method of production of same can be utilized for copper foil with resistance layers used for resistance element for rigid substrate and flexible substrate and the method of production of same.

### REFERENCE SIGNS LISTS

1 Base substrate copper foil
3 Resistance layer
4 Nickel particles
22 First treatment tank (resistance layer formation step)
26 Second treatment tank (roughening treatment step)
30 Third treatment tank (capsule plating step)
37 Fourth treatment tank (rust prevention treatment step)
42 Fifth treatment tank (silane coupling)
44 Drying step

1. A copper foil with a resistance layer comprising a copper foil on one surface of which a metal layer or alloy layer is formed from which a resistance element is to be formed, the surface of the metal layer or alloy layer being subjected to a roughening treatment with nickel particles.

2. A copper foil with a resistance layer comprising a copper foil on one surface of which a metal layer or alloy layer is formed form which a resistance element is to be formed, the surface of the metal layer or alloy layer being subjected to a roughening treatment with nickel particles, the surface subjected to the roughening treatment being plated by capsule plating.

3. A copper foil with a resistance layer comprising a copper foil on one surface of which a metal layer or alloy layer is formed from which a resistance element is to be formed, the surface of the metal layer or alloy layer being subjected to a roughening treatment with nickel particles, on the surface subjected to the roughening treatment a chromate rust prevention layer being formed.

4. A copper foil with a resistance layer comprising a copper foil on one surface of which a metal layer or alloy layer is formed from which a resistance element is to be formed, the surface of the metal layer or alloy layer being subjected to a roughening treatment with nickel particles, on the surface subjected to the roughening treatment a chromate rust prevention layer being formed, and on the surface of the rust prevention layer a thin film layer of a silane coupling agent being formed.

5. A copper foil with a resistance layer as set forth in any one of claims 1 to 4, wherein the copper foil is an electrodeposited copper foil having crystals comprised of columnar crystal grains, the metal layer or alloy layer from which the resistance element is to be formed is formed on a matte surface of the electrodeposited copper foil, and a foundation of the matte surface is within a range of 2.5 to 6.5 μm in terms of Rz value prescribed in JIS-B-0601.

6. A copper foil with a resistance layer as set forth in any one of claims 1 to 5, wherein an elongation of the electrodeposited copper foil at ordinary temperature after heating at 180° C. for 60 minutes under atmospheric heating conditions is 12% or more.

7. A copper foil with a resistance layer as set forth in any one of claims 1 to 6, wherein a roughness after the nickel roughening treatment is within a range of 4.5 to 8.5 μm in terms of Rz value prescribed in JIS-B-0601.

8. A copper foil with a resistance layer as set forth in claim 3 or 4, wherein a deposition amount of chromium in terms of chromium metal in the chromate rust prevention layer is 0.005 to 0.045 mg/dm².

9. A copper foil with a resistance layer as set forth in claim 4, wherein a deposition amount of the silane coupling agent in terms of silicon in the thin film layer of the silane coupling agent is 0.001 to 0.015 mg/dm².

10. A method of production of a copper foil with a resistance layer comprising: forming a resistance layer of phosphorus-containing nickel on a matte surface of an electrodeposited copper foil having crystals comprised of columnar crystal grains wherein a foundation of the matte surface is within a range of 2.5 to 6.5 μm in terms of Rz value prescribed in JIS-B-0601; and performing roughening treatment to a surface of the resistance layer with nickel particles wherein a roughness is within a range of 4.5 to 8.5 μm in terms of Rz value prescribed in JIS-B-0601.

11. A method of production of a copper foil with a resistance layer as set forth in claim 10, wherein an elongation of the electrodeposited copper foil at ordinary temperature after heating at 180° C. for 60 minutes under atmospheric heating conditions is 12% or more.

12. A laminated board comprising a copper foil with a resistance layer as set forth in any one of claims 1 to 9 mounted on a rigid substrate or a flexible substrate having an embedded device, the copper foil with the resistance layer being patterning etched.
